(19) United States
(12) Patent Application Publication
(10) Pub. No.: US 2008/0087213 A1
(43) Pub. Date: Apr. 17, 2008

(54) Method for fabricating a semiconductor device, method for fabricating an electronic device, and semiconductor fabricating apparatus

(75) Inventors: Mitsuru Sato, Suwa-shi (JP); Sumio Utsunomiya, Matsumoto-shi (JP)

Correspondence Address: OLIFF & BERRIDGE, PLC, P.O. BOX 320850, ALEXANDRIA, VA, 22320-4850, US

(73) Assignee: SEIKO EPSON CORPORATION, Tokyo (JP)

(21) Appl. No.: 11/905,930

(22) Filed: Oct. 5, 2007

(30) Foreign Application Priority Data
Oct. 11, 2006 (JP) 2006-277956

(51) Int. Cl. B05C 11/00; H01L 21/477

(52) U.S. Cl. 118/47; 438/795; 257/E21.497

(57) ABSTRACT

A method for fabricating a semiconductor device including: a step of forming a first film on a substrate; and a step of performing a thermal process by scanning the first film with a flame of a gas burner using a hydrogen and oxygen gas mixture as a fuel, wherein the flame of the gas burner is approximately linear.

### CROSS-REFERENCES TO RELATED APPLICATIONS

The entire disclosure of Japanese Patent Application No. 2006-277956, filed on Oct. 11, 2006 is expressly incorporated by reference herein.

### BACKGROUND

1. Technical Field

The present invention relates to a method for fabricating a semiconductor device particularly to improving the uniformity of the thermal processing temperature during a thermal processing step.

2. Related Art

Crystallization methods designed to recrystallize silicon formed as a film on a substrate using a CVD (chemical vapor deposition) method include solid phase growth utilizing a process of high temperature heating at 600 to 1,000° C., laser annealing methods utilizing excimer laser emission, thermal plasma jet methods utilizing thermal plasma as a heat source and the like (JP-A-11-145148; Crystallization of Si Thin Film Using Thermal Plasma Jet and Its Application to Thin-Film Transistor Fabrication, S. Higashi, AM-LCD '04 Technical Digest Papers, p. 179).

### SUMMARY

In methods of solid phase growth by the above thermal process, the substrate is subject to a large thermal load which may easily cause warping and cracking of the substrate because the substrate is heated to a high temperature between 600 and 1,000° C. Furthermore, mass production characteristics are poor because a long time is needed for crystallization. Although laser annealing methods can use glass substrates with low heat resistance, such equipment is expensive and there is a tendency for large dispersion of element characteristics.

The present inventors have conducted diligent investigations of thermal processing in which the flame of a gas burner using a hydrogen and oxygen gas mixture as a fuel in order to improve processing characteristics as a semiconductor device fabricating method capable of thermally processing a large surface area substrate while reducing the thermal load on the substrate (for example, refer to Japanese Patent Application No. 2005-329205).

Heterogeneity was observed in films after the films were subjected to thermal processing, and our research has determined that uneven thermal processing temperature was the cause.

An advantage of some aspects of the present invention is to provide a method for fabricating a semiconductor device capable of thermally processing a large surface area substrate while reducing the thermal load on the substrate. A further advantage of some aspects of the present invention is to improve the uniformity of the thermal processing temperature and improve the characteristics of the formed semiconductor device.

(1) The method for fabricating a semiconductor device of the present invention includes a step of forming a first film on a substrate, and a step of performing a thermal process by scanning the first film with a flame of a gas burner using a hydrogen and oxygen gas mixture as a fuel, the flame of the gas burner being approximately linear.

This method improves the uniformity of the thermal processing temperature because thermal processing is accomplished by scanning with a linear flame.

(2) The method for fabricating a semiconductor device of the present invention includes a step of forming a first film on a substrate, and a step of performing a thermal process by scanning the first film with a flame of a gas burner using a hydrogen and oxygen gas mixture as a fuel, the flame of the gas burner being a plurality of flames arrayed in an approximately linear fashion.

This method improves the uniformity of the thermal processing temperature because the ends of adjacent flames overlap on the substrate.

The overlap of the flames is adjusted, for example, by changing the distance between the gas burner and the substrate. According to this method, the flame overlap can be easily adjusted, and the uniformity of the thermal processing temperature is improved.

(3) The method for fabricating a semiconductor device of the present invention includes a step of forming a first film on a substrate, and a step of performing a thermal process by scanning the first film with a plurality of flames of a gas burner arrayed in an approximately linear fashion at fixed spacing using a hydrogen and oxygen gas mixture as a fuel, wherein the step of performing a thermal process includes a first step of scanning the plurality of flames in a first direction, and a second step of scanning in the first direction after moving the plurality of flames a distance ½ the fixed spacing distance in a second direction which is perpendicular to the first direction.

This method scans those regions which are between the flames in the first step with the flames in the second step, thus reducing the heterogeneity of the processed film caused by a temperature differential in the thermal process.

For example, the first step is a step of scanning the plurality of flames from the side of a first end of the substrate and the second step is a step of scanning the plurality of flames from a second end on the side opposite the first end of the substrate. This method is capable of high speed processing.

For example, the first film is a semiconductor film, and the semiconductor film is subjected to recrystallization by the thermal process. This method is capable of recrystallizing a semiconductor film, and reducing dispersion in the size of the crystal grains.

(4) The method for fabricating an electronic device of the present invention has the method for fabricating a semiconductor device. This method is capable of fabricating an electronic device that has excellent characteristics. The electronic device includes display devices and the like fabricated using the method for fabricating a semiconductor device of the present invention, and the electronic device further includes video cameras, large screens, portable telephones, personal computers portable information devices (so-called PDA), and other types of devices.

(5) The semiconductor fabricating apparatus of the present invention includes a gas supplying unit for supplying a hydrogen and oxygen gas mixture, a gas burner for combusting the hydrogen and oxygen gas mixture to form a flame, and a moving unit that relatively moves a substrate in a direction perpendicular to the flame of the gas burner, wherein the gas burner conducts the hydrogen and oxygen gas mixture and emits the flame from an approximately linear orifice.

This configuration improves the uniformity of the thermal process by emitting a flame from an approximately linear orifice.

(6) The semiconductor fabricating apparatus of the present invention includes a gas supplying unit for supplying a hydrogen and oxygen gas mixture, a gas burner for combusting the hydrogen and oxygen gas mixture to form a flame, and a moving unit that relatively moves a substrate in a direction perpendicular to the flame of the gas burner, wherein the gas burner conducts the hydrogen and oxygen gas mixture, and emits the plurality of flames from a plurality of orifices formed in an approximately linear fashion at uniform pitch.

This configuration is capable of thermally processing a film on a substrate by emitting a plurality of flames from a plurality of orifices formed in an approximately linear fashion at uniform pitch.

For example, a nozzle having an approximately linear orifice is provided below the plurality of flames, and the plurality of flames are emitted through the orifice. This configuration improves the uniformity of the thermal process by emitting a flame from an approximately linear orifice of the nozzle.

For example, the moving unit controls movement in a first direction and a second direction which is perpendicular to the first direction. This configuration improves the uniformity of the thermal process by controlling the movement of the substrate in a second direction ½ the distance of the fixed pitch after the substrate has been moved in the first direction, then moving the substrate again in the first direction.

### BRIEF DESCRIPTION OF THE DRAWINGS

FIG. 1 shows a structural example of the semiconductor fabricating apparatus used to fabricate the semiconductor device of the embodiment;

FIG. 2 is a top view showing a structural example of the gas burner of the semiconductor fabricating apparatus;

FIG. 3 is a cross section view showing a structural example of the gas burner of the semiconductor fabricating apparatus;

FIG. 4 shows a first structural example of the gas burner of the semiconductor fabricating apparatus;

FIG. 5 shows a second structural example of the gas burner of the semiconductor fabricating apparatus;

FIG. 6 shows a third structural example of the gas burner of the semiconductor fabricating apparatus;

FIG. 7 shows the relationship between the height of the nozzle and the gas outflow pressure;

FIG. 8 shows the relationship between the shape and angle of the nozzle and the gas outflow pressure;

FIG. 9 shows the relationship between the gas outflow pressure and the distance between the nozzle and the guide tube;

FIG. 10 is a cross section view showing the semiconductor fabricating process investigated by the present inventors;

FIG. 11 is a graph showing the post recrystallization silicon film thickness, silicon oxide film thickness, and crystallization rate of sample A;

FIG. 12 is a graph showing the post recrystallization silicon film thickness, silicon oxide film thickness, and crystallization rate of sample B;

FIG. 13 is a graph showing the post recrystallization silicon film thickness, silicon oxide film thickness, and crystallization rate of sample C;

FIG. 14 is a graph showing the post recrystallization silicon film thickness, silicon oxide film thickness, and crystallization rate of sample D;

FIG. 15 is a graph showing the post recrystallization silicon film thickness, silicon oxide film thickness, and crystallization rate of sample E;

FIG. 16 shows the hydrogen flame process and substrate measurement position;

FIG. 17 is a cross section view of semiconductor device fabricating method 1;

FIG. 18 shows a bottom view, cross section view, and another cross section view of the gas burner structure;

FIG. 19 is a cross section view of semiconductor device fabricating method 1;

FIG. 20 shows the overlapping spot flames of the gas burner;

FIG. 21 is a top view showing the hydrogen flame scanning method in the semiconductor device fabricating method 4; and

FIG. 22 shows an example of electronic devices using an electro-optic device.

### DESCRIPTION OF EXEMPLARY EMBODIMENTS

In the present embodiment, thermal processing is performed on a film on a substrate using a hydrogen and oxygen gas mixture as a fuel. This thermal process is referred to as the hydrogen flame process hereinafter. Furthermore, the flame of the gas burner is referred to as the hydrogen flame. This thermal process is performed, for example, when recrystallizing a silicon film (semiconductor film, semiconductor layer).

The embodiments of the present invention are described hereinafter with reference to the figures. Parts having like functions are designated by like reference numbers, and repetitious description is omitted.

Semiconductor Fabricating Apparatus

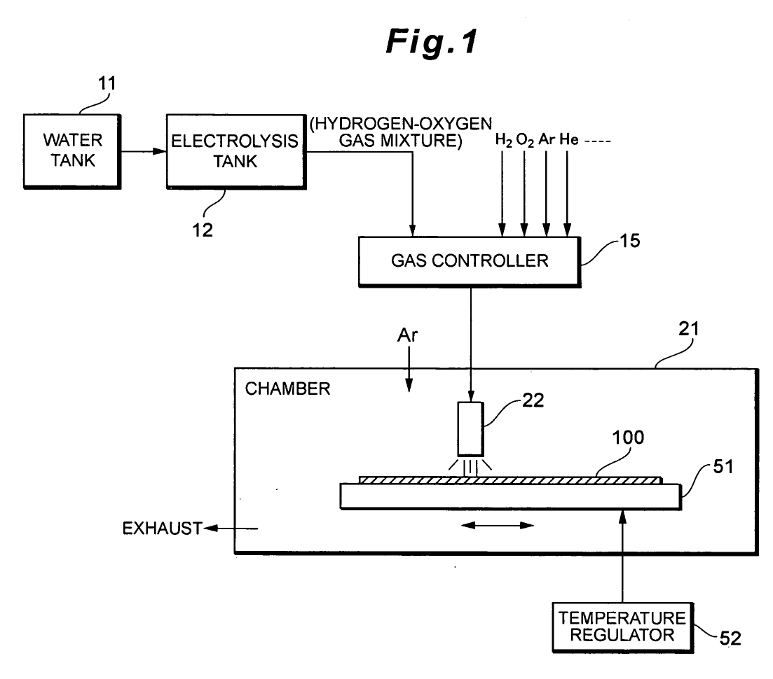

A semiconductor fabricating apparatus used to fabricate the semiconductor device of the present embodiment is described hereinafter with reference to FIGS. 1 through 9.

FIG. 1 shows a structural example of the semiconductor fabricating apparatus (semiconductor element fabricating apparatus) used to fabricate the semiconductor device of the present invention. In FIG. 1, purified water is stored in a water tank 11, and this water is supplied to an electrolysis tank (electrolysis device) 12. The water is electrolyzed by the electrolysis tank 12 and hydrogen gas and oxygen gas are released therefrom. The released hydrogen gas and oxygen gas are supplied to a gas controller 15. The gas controller 15 is configured by a computer system, regulator valve, and various types of sensors, and the gas controller 15 adjusts the amount, pressure and ratio of the hydrogen gas and oxygen gas (gas mixture) supplied to a downstream gas burner 22 in accordance with a preset program.

The gas controller 15 conducts the hydrogen gas (H₂) and oxygen gas (O₂) supplied from a gas storage tank which is not shown in the figure to form the previously mentioned gas mixture, which is then supplied to the gas burner 22. Thus, mixture ratio of the hydrogen gas and the oxygen gas of the gas mixture is shifted from the stoichiometric composition ratio of water (H₂O) (H₂:O₂=2 mol:l mol), to obtain a gas mixture of excess hydrogen (hydrogen rich) or excess oxygen (oxygen rich).

Furthermore, the gas controller 15 is supplied gas from a storage tank which is not shown in the figure so as to introduce inactive gases such as argon (Ar), helium (He), nitrogen (N₂) and the like into the has mixture. Thus, controlling the flame condition and flame temperature (combustion temperature) of the gas burner 22.

The water tank 11, electrolysis tank 12, and gas controller 15 configure a fuel (source material) supply unit.

A chamber (processing compartment) 21 is disposed in a closed space downstream from the gas controller 15. Disposed within this chamber 21 is a gas burner 22 for generating the flame of the heating process, and a stage (mounting dais) 51 which is movable relative to the burner 22 and on which is installed a processing object substrate (semiconductor substrate, glass substrate and the like) 100.

The atmosphere within the chamber 21 is not limited, and may be set, for example, at an internal pressure ranging from approximately atmospheric pressure to 0.5 MPa, and the internal temperature may be set in a range from approximately ambient temperature to 100° C. The previously mentioned argon or other inert gas may be introduced into the chamber 21 to maintain a desired gas pressure within the chamber 21.

The stage 51 is provided with a mechanism for moving the dais on which the substrate is installed at a fixed speed to prevent particles. To prevent heat shock of the substrate 100 caused by a rapid temperature differential, a mechanism is provided to heat (preheat) and cool the mounting dais of the substrate 100, and temperature control is performed by an external temperature controller 52. An electric heating device is used for heating and a cooling device which employs coolant gas and coolant liquid is used for cooling.

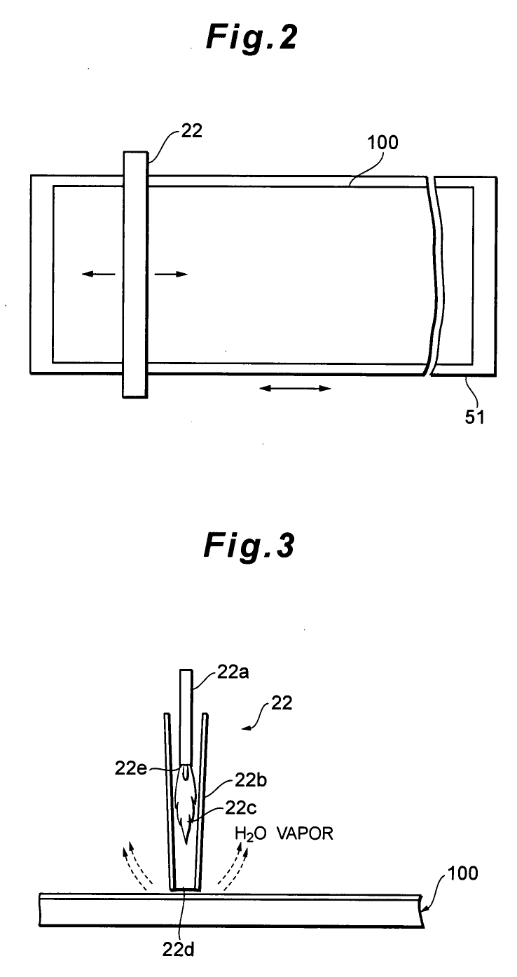

FIG. 2 is a top view showing an example of the gas burner structure of the semiconductor fabricating apparatus. As shown in FIG. 2, the gas burner 22 of the semiconductor fabricating apparatus of FIG. 1 is configured by a long member which is larger than the width of the stage 51 (vertical direction in the figure), and can emit a flame with a width larger than the width of the stage 51. The gas burner 22 is configured so as to scan the substrate 100 by moving either the stage 51, or the gas burner 22, in a direction perpendicular to the lengthwise direction of the gas burner 22 (arrow direction in the figure).

FIG. 3 is a cross section view showing an example of the gas burner structure of the semiconductor fabricating apparatus. As shown in FIG. 3, the gas burner 22 is configured by a guide tube 22a provided with a gas outlet for guiding the gas mixture to the combustion compartment, a shield 22b which circumscribes the guide tube 22a, a combustion compartment 22c for combusting the gas mixture and circumscribed by the shield 22b, nozzle 22d which forms an outlet to emit the combusted gas from the shield 22b, and gas mixture flow outlet 22e provided on the guide tube 22a.

When the gap (distance) between the nozzle 22d and the substrate 100 is set wide, the pressure is reduced as the combusted gas is released from the nozzle. When the gap between the nozzle 22d and the substrate 100 is set narrow (constructed), the pressure is increased since the combusted gas pressure reduction is suppressed. Therefore, the gas pressure can be adjusted by adjusting this gap. Water vapor annealing, hydrogen annealing, oxygen annealing and the like can be promoted by increasing the pressure. Each type of annealing is selectable by the setting of the gas mixture. The figure shows the emission of water valor (H₂O vapor).

The shape of the flame (flame length) of the combustion compartment 22c of the gas burner 22 can be a linear (long flame), or a plurality of torches by configuring the gas mixture outlet 22e as linear or a plurality. The temperature profile near the gas burner 22 is desirably set so as to be rectangular in the flame scanning direction via the design of the nozzle 22d of the shield 22b and the outlet 22e.

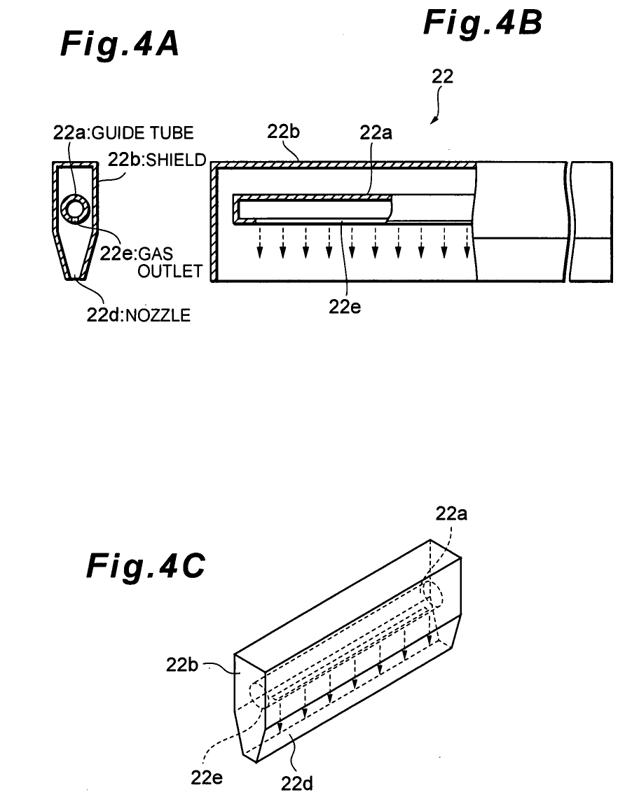

FIG. 4 shows a first structural example of the gas burner of the semiconductor fabricating apparatus. FIG. 4A is a cross section view of the gas burner 22 in the foreground direction, FIG. 4B is a partial cross section view of the gas burner 22 in the length direction, and FIG. 4C is a perspective view the gas burner schematics. In these figures, parts in common with FIG. 3 are designated by like reference numbers.

In this example, the shield 22b is configured so as to circumscribe the guide tube 22a. The lower part of the shield 22b becomes the nozzle 22d, and the gas flow outlet 22e is provided so as to be linear (slot) below the guide tube 22a (nozzle 22d side). The width of the orifice may change according to the location to achieve the same outflow at each position of the linear gas outlet 22e.

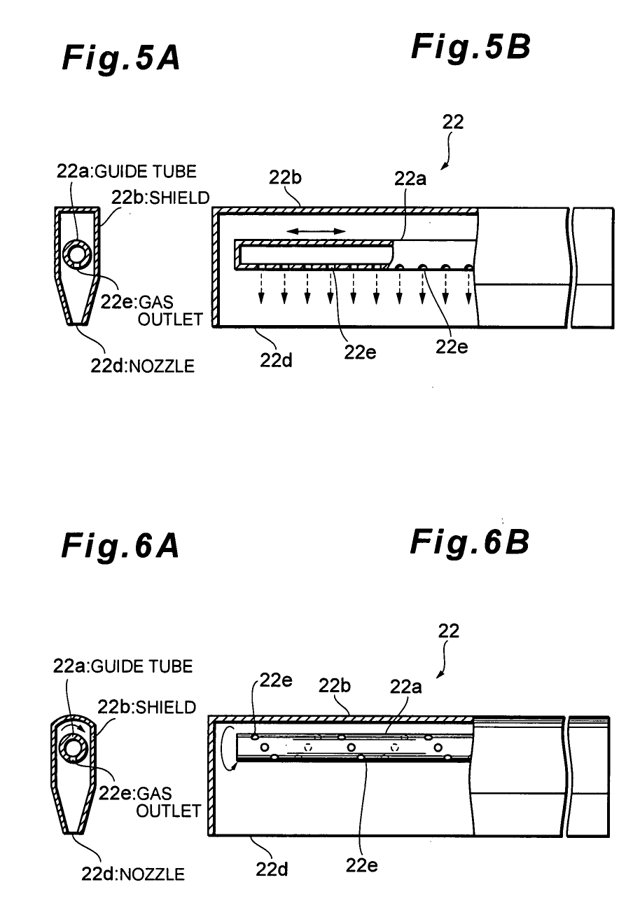

FIG. 5 shows a second structural example of the gas burner of the semiconductor fabricating apparatus. Another structural example of the gas burner 22 is shown. FIG. 5A is a cross section view of the gas burner 22 in the foreground direction, and FIG. 5B is a partial cross section view of the gas burner 22 in the length direction. In both figures, parts in common with. FIG. 3 are designated by like reference numbers.

In this example, the shield 22b is configured so as to circumscribe the guide tube 22a. The lower part of the shield 22b becomes the nozzle 22d, and a plurality of gas flow outlets 22e are provided at equal spacing at lower part of the guide tube 22a (nozzle 22d side). In this configuration, the combustion chamber gas density is uniform, and the guide tube 22a is suitably movable, for example, in a lateral direction in the figure in order to make a uniform amount of gas flow from the nozzle 22d to the outside. The distance of the gas outlet 22e may change as needed according to the location to fix the guide tube 22a and achieve the same outflow at each position of the gas outlet 22e.

FIG. 6 shows a third structural example of the gas burner of the semiconductor fabricating apparatus. FIG. 6A is a cross section view of the gas burner 22 in the foreground direction, and FIG. 6B is a partial cross section view of the gas burner 22 in the lengthwise direction. In both figures, parts in common with FIG. 3 are designated by like reference numbers.

In this example, the shield 22b is configured so as to circumscribe the guide tube 22a. The lower part of the shield 22b becomes the nozzle 22d, and a plurality of gas flow outlets 22e are provided at equal spacing in a spiral shape on the side surface of the guide tube 22a. In this configuration, the combustion chamber gas density is uniform, and the guide tube 22a is rotatable as indicated by the arrow in the figure in order to make a uniform amount of gas flow from the nozzle 22d to the outside.

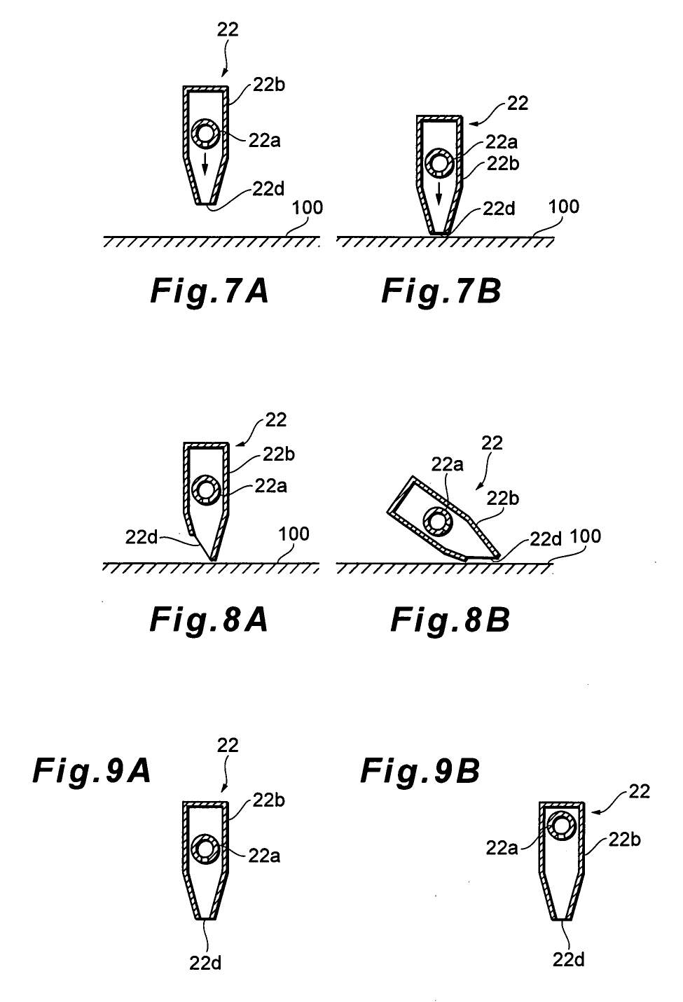

FIG. 7 shows the relationship between the height of the nozzle and the gas outflow pressure. As shown in FIG. 7A, the outflow combustion gas pressure can be reduced by distancing the nozzle 22d from the surface of the substrate 100. As shown in FIG. 7B, the outflow combustion gas pressure can be increased by advancing the nozzle 22d to the surface of the substrate 100.

FIG. 8 shows the relationship between the shape and angle of the nozzle and the gas outflow pressure. As shown in FIG. 8, the gas outflow pressure can be adjusted by adjusting the orientation and shape of the nozzle 22d (adjusting the shape of the outlet and the angle relative to the substrate). In this example, the outlet shape of the nozzle 22d is open on one side, as shown in FIG. 8A. Therefore, the combustion gas outflow pressure can be reduced when the gas burner 22 assumes an upright position. As shown in FIG. 8B, combustion gas outflow pressure can be increased when the gas burner 22 is rotated or inclined and the outlet of the nozzle 22d approaches the surface of the substrate 100.

FIG. 9 shows the relationship between the gas outflow pressure and the distance between the nozzle and the guide tube. As shown in FIG. 9, the temperature of the combustion gas flowing from the nozzle 22d is adjustable by varying the relative positional relationship between the guide tube 22a and the shield 22b. For example, the guide tube 22a may be configured to be advanceable and retractable toward the nozzle 22d within the shield 22b, so as to move the combustion compartment 22c and change the distance between the heat source and the nozzle 22d. The distance between the heat source and the substrate may also be adjustable.

Therefore, the combustion gas flowing from the nozzle 22d has a relatively high temperature when the guide tube 22a is brought relatively near the nozzle 22d, as shown in FIG. 9A. Furthermore, the combustion gas flowing from the nozzle 22d has a relatively low temperature when the guide tube 22a is relatively distanced from the nozzle 22d, as shown in FIG. 9B.

Such a configuration is advantageous since the temperature of the outflow combustion gas is adjustable without changing the gap between the gas burner 22 and the substrate 100. The substrate temperature may of course also be adjusted by changing the gap between the gas burner 22 and the substrate 100. The gas temperature may of course also be adjusted by changing the gap between the gas burner 22 and the substrate 100 and adjusting the relative positional relationship between the guide tube 22a and the shield 22b. The substrate temperature may also be adjusted by changing the scanning speed of the gas burner 22 relative to the substrate.

The gas burner configurations shown in FIGS. 4 through 9 may be suitably combined.

The configuration shown in FIG. 7 and the configuration shown in FIG. 9 may be combined, for example. The temperature of the substrate 100 (for example, the surface temperature) can be adjusted by making the gap adjustable between the nozzle 22d and the substrate 100 so as to have the entirety of the gas burner 22 shown in FIG. 7 approach or retract from the substrate 100. Furthermore, the temperature of the substrate 100 can be finely adjusted by advancing or retracting the guide tube 22a within the gas burner 22 toward the nozzle 22d, as shown in FIG. 9. Therefore, the temperature of the substrate 100 can be more easily set at a target thermal processing temperature.

The configurations shown in FIGS. 7 and 8 may also be combined. The surface temperature of the substrate 100 and flame pressure can be adjusted by making the gap adjustable between the nozzle 22d and the substrate 100 so as to have the entirety of the gas burner 22 approach or retract from the substrate 100 (refer to FIG. 7). The surface temperature of the substrate 100 and the flame pressure may then be adjusted by adjusting the orientation of the entirety of the gas burner 22 relative to the substrate 100 (refer to FIG. 8).

The configurations shown in FIGS. 7, 8, and 9 may also be combined. The temperature of the substrate 100 and flame pressure can be coarsely adjusted by making the gap adjustable between the nozzle 22d and the substrate 100 so as to have the entirety of the gas burner 22 approach or retract from the substrate 100 (refer to FIG. 7). The surface temperature of the substrate 100 and the flame pressure may then be adjusted by adjusting the orientation of the entirety of the gas burner 22 relative to the substrate 100 (refer to FIG. 8). The surface temperature of the substrate 100 may then be finely adjusted by advancing or retracting the guide tube 22a within the gas burner 22 toward the nozzle 22d (refer to FIG. 9). More accurate thermal processing is possible by this configuration.

Although not shown in the figures, the orifice (outlet, diaphragm) of the nozzle 22d may also be modifiable so as to widen and narrow in the scanning direction of the gas burner 22 by having the shield plate 22b of the gas burner 22 a movable type. Thus, the exposure time of the processed part of the substrate 100 in the scanning direction of the gas burner 22, the temperature profile of the thermal process of the substrate 100, the temperature of the thermal process, and the flame pressure and the like are adjustable.

In the above described semiconductor fabricating apparatus, the thermal process can be performed on a large surface area substrate such as window glass since a long gas burner is provided which is capable of transecting the substrate. Furthermore, obtaining the gas fuel is simple and running costs are inexpensive since the hydrogen and oxygen used as fuel can be obtained by electrolyzing water.

Although the gas burner 22 is provided with a shield 22b in the above described semiconductor fabricating apparatus, processing may also be performed with the gas burner 22 exposed to the outside air without using the shield 22b, that is with a direct flame emitted from the guide tube 22a. Although the semiconductor fabricating apparatus above has been described in terms of a combustion gas discharged from the shield 22b, adjustment may be made for the flame to emerge from the shield 22b.

The processing of the substrate may be accomplished via the combustion gas or direct contact with the flame. Control of these processes is achieved by suitably setting each condition of each process.

In particular, the flame may be set according to conditions so as to have a strongly reductive inner flame (reductive flame) and a strongly oxidative outer flame (oxidative flame), either of which may contact the substrate. Furthermore, the inner flame has a relatively low temperature (approximately 500° C.) and the outer flame has a relatively high temperature (approximately 1400 to 1500° C.). Between the inner flame and outer flame is a high temperature of approximately 1800° C. Therefore, the flame can be set according to the processing conditions.

In the thermal processing step, a reductive atmosphere (hydrogen rich) or oxidative atmosphere (oxygen rich) can be easily set by suitably setting the mixture ratio of hydrogen and oxygen and the amount of gas mixture being supplied.

Since the hydrogen and oxygen of the fuel can be obtained by electrolyzing water, a gas mixture of hydrogen and oxygen having the stoichiometric ratio of 2 mol:1 mol of water (H₂O) can be easily obtained, and a reductive atmosphere (hydrogen rich) or oxidative atmosphere (oxygen rich) can be easily obtained by specially adding oxygen or hydrogen to the gas mixture.

The flame temperature is also easily adjustable. The flame condition (temperature, gas pressure and the like) can be adjusted by introducing an inert gas, or adjusting the amount of the source material gas flow as necessary.

A desired temperature profile is easily obtained by adjusting the gas burner nozzle shape and the like.

The process using the gas burner has high mass production characteristics and is inexpensive. The burden on the environment (environmental damage) is reduced since the hydrogen and oxygen providing the source material gas for the flame provide clean energy and the main product is water.

Method for Fabricating a Semiconductor Device

In this embodiment of the present invention, a hydrogen flame process is performed using the semiconductor fabricating apparatus mentioned above. An example is described below in which a silicon film (semiconductor film, semiconductor layer) is recrystallized via a heating process using the gas burner and a hydrogen and oxygen gas mixture as a fuel.

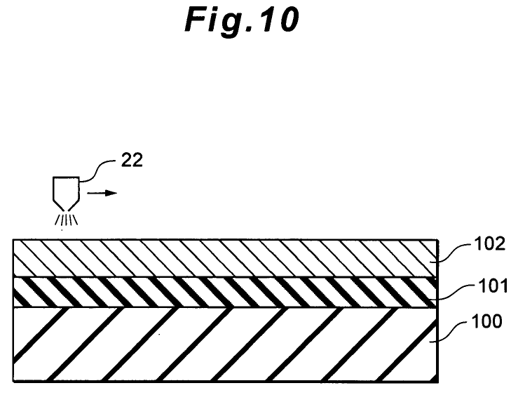

The experimental results of the present inventors are described first. The recrystallization of a silicon film was accomplished as follows. FIG. 10 is a cross section view showing the semiconductor fabricating process investigated by the present inventors.

As shown in FIG. 10, an undercoat protective film 101 is formed on a glass substrate 100, then a silicon film 102 is formed on the top of the undercoat film, after which the silicon film 102 is subjected to a hydrogen flame process to recrystallize the silicon.

That is, a substrate 100 is loaded on the stage 51 (refer to FIG. 1), and thermal processing is performed by having the gas burner 22 scan over the substrate 100 (silicon film 102) with the gas burner 22 to render the silicon film 102 as a polycrystal silicon film. At this time the surface of the polycrystal silicon film is oxidized to form a silicon oxide film.

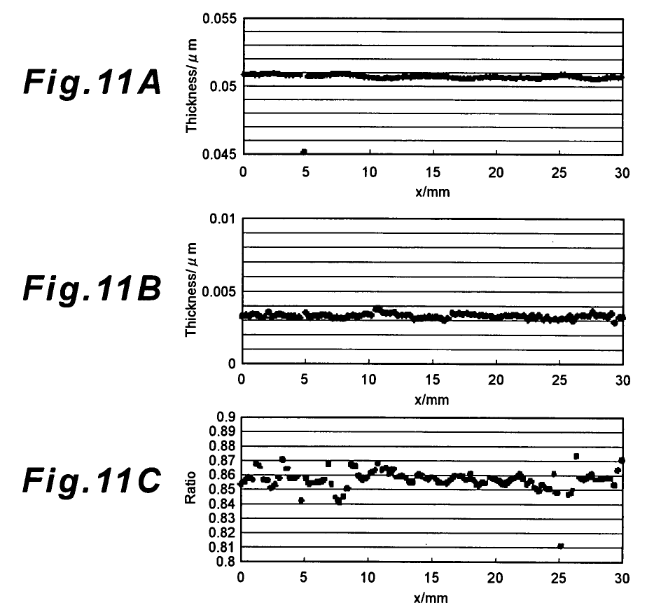

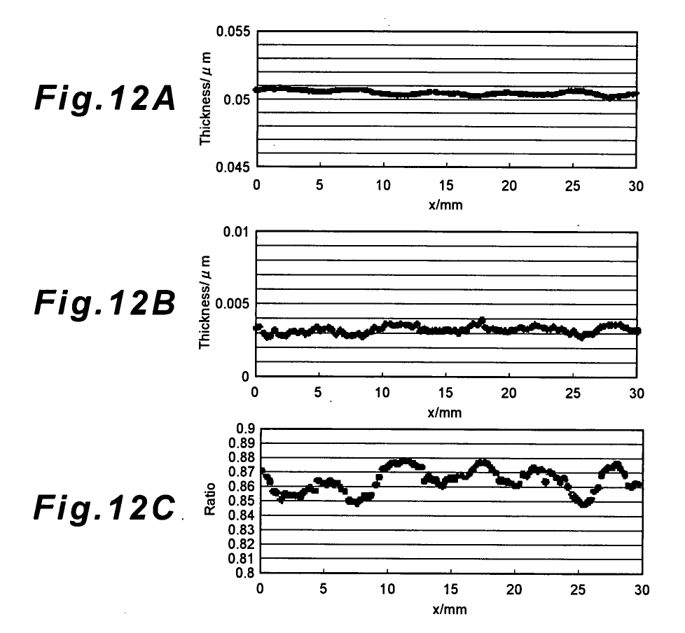

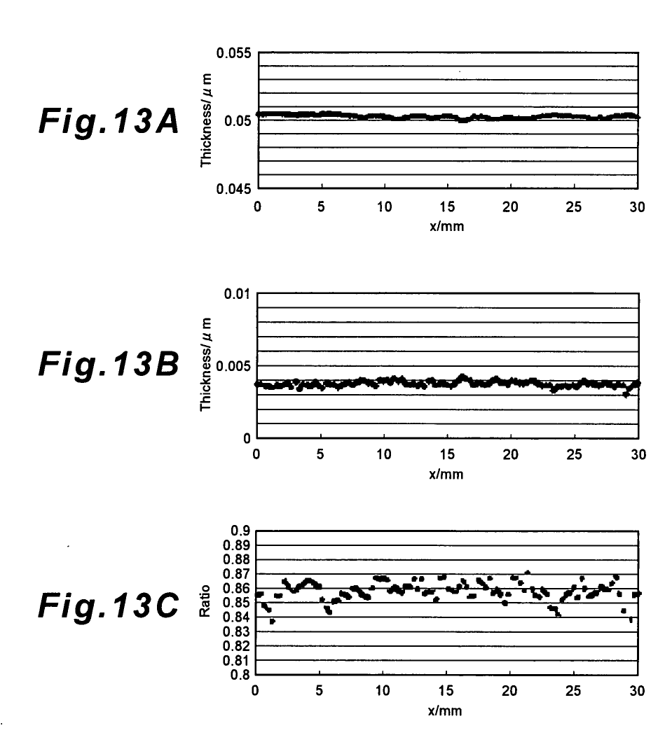

Five samples A through E were subjected to the hydrogen flame process under various conditions, and the silicon film thickness after recrystallization (polycrystal silicon film thickness), the silicon oxide film thickness, and crystallization rates were measured. The results are shown in FIGS. 11 through 15, respectively. In the figures, (A) shows the silicon film thickness after recrystallization [Thickness], (B) shows the silicon oxide film thickness [thickness], and (C) shows the crystallization ratio [Ratio].

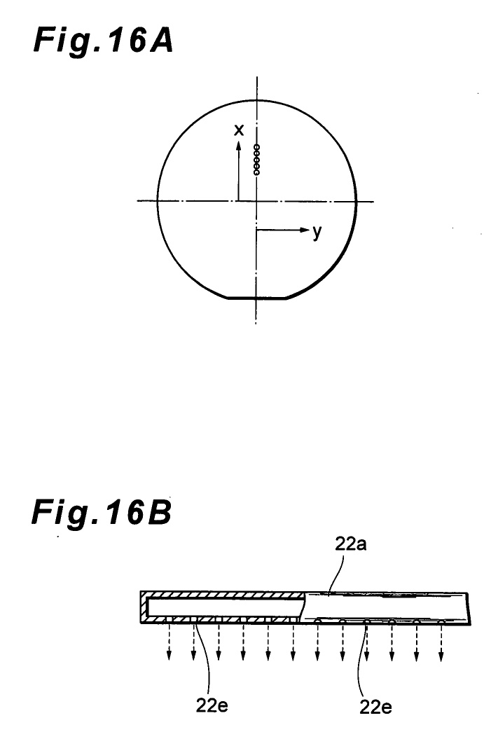

After the hydrogen flame process was performed under the conditions described below, each sample was set at measurement positions at spacing of 0.3 mm and 30 mm in the x direction shown in FIG. 16A, and the crystallization rate and the like were measured at this point. The hydrogen flame process shown in FIG. 16B was performed by scanning in the y direction shown in FIG. 16A with a flame emitted from a guide tube 22a provided with a plurality of hole-like gas outlets 22e. FIG. 16 shows the hydrogen flame process and measurement position. The gap represents the distance between the substrate and the gas burner (orifice).

Sample A was processed with the gap set at 50 mm and the scanning speed at 62 mm/s; sample B at a gap of 50 mm and scanning speed of 50 mm/s; sample C at a gap of 30 mm and scanning speed of 98 mm/s; sample D at a gap of 30 mm and scanning speed of 65 mm/s; sample E at a gap of 30 mm and scanning speed of 38 mm/s.

The substrate temperature was highest in sample E at 889° C. The thickness of the silicon film was approximately 0.051 μm in samples A through D, and the thickness of the silicon oxide film on the surface was approximately 0.004 μm, as shown in FIGS. 11 through 15. The silicon oxide film was formed by the silicon film reacting with the oxygen in the air or oxygen in the flame.

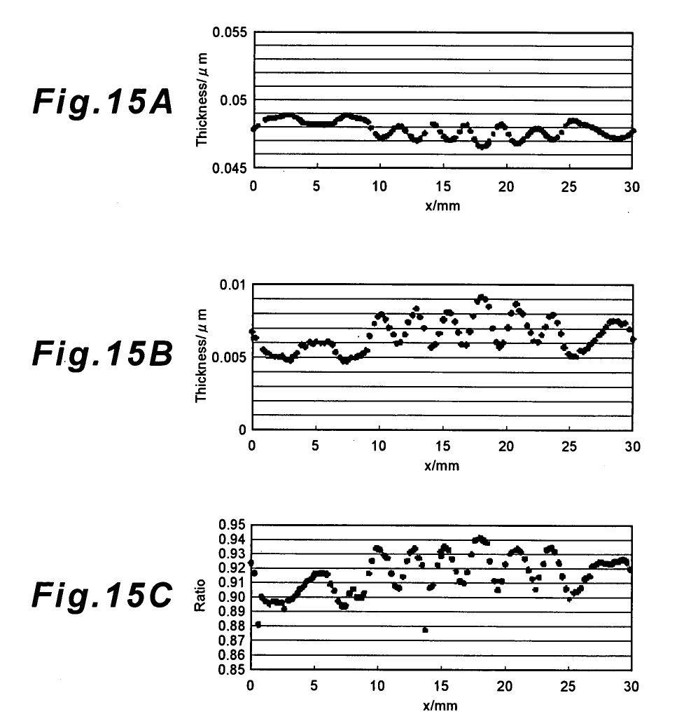

The crystallization rate was approximately 0.87 to 0.89 in samples A through D. Excellent crystals were obtained in sample E (FIG. 15) which had the highest crystallization rate at approximately 0.94 (94%). In this case, the silicon film was approximately 0.04 μm thick, and the silicon oxide film was approximately 0.009 μm thick. The degree of oxidation of the surface of the silicon film was greater in sample E than in other samples.

The data reveal that a high substrate surface temperature is obtained and the crystallization rate is improved by reducing the gap and scanning relatively slowly.

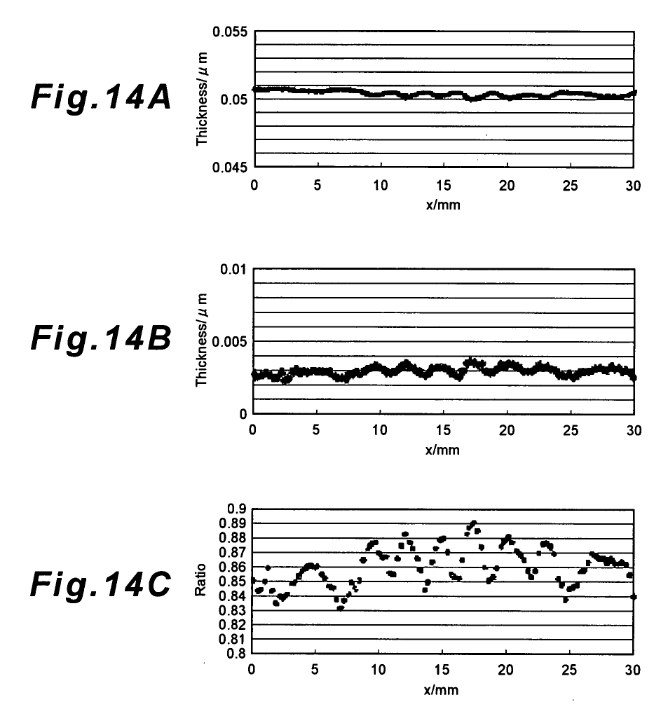

Pronounced dispersion was observed in post recrystallization silicon film thickness, silicon oxide film thickness, and crystallization rate in conjunction with decreasing scanning speed, as can be understood from FIG. 14 (sample D), and FIG. 15 (sample E).

This phenomenon is investigated below. That is, flames are emitted using the guide tube 22a on which are formed a plurality of gas outlets (orifices) 22e formed at fixed pitch in an approximately linear fashion to conduct the hydrogen and oxygen gas mixture, as shown in FIG. 16B. The flame that is emitted from a single orifice is referred to as a spot flame. The flame temperature is highest directly below the orifice 22e and the flame temperature decreases between spot flames, which is thought to be the cause of the relative reduction of the flame temperature between orifices 22e.

Thus, reducing film unevenness (dispersion of film thickness, dispersion of crystallization rate) by improving the uniformity of the flame temperature can be considered.

The method for fabricating a semiconductor device of the present invention improves thermal processing characteristics by improving the uniformity of the flame temperature.

Fabricating Method 1

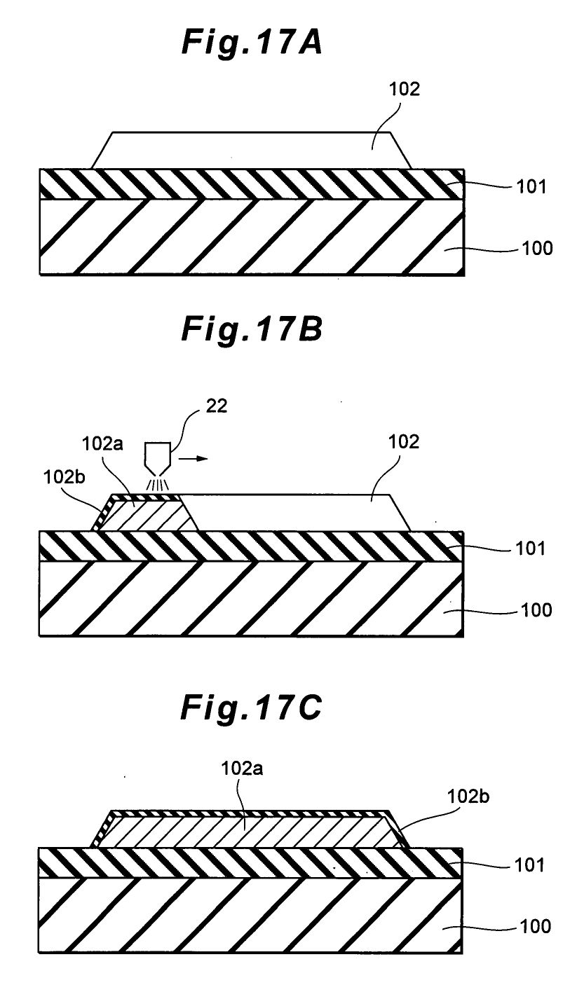

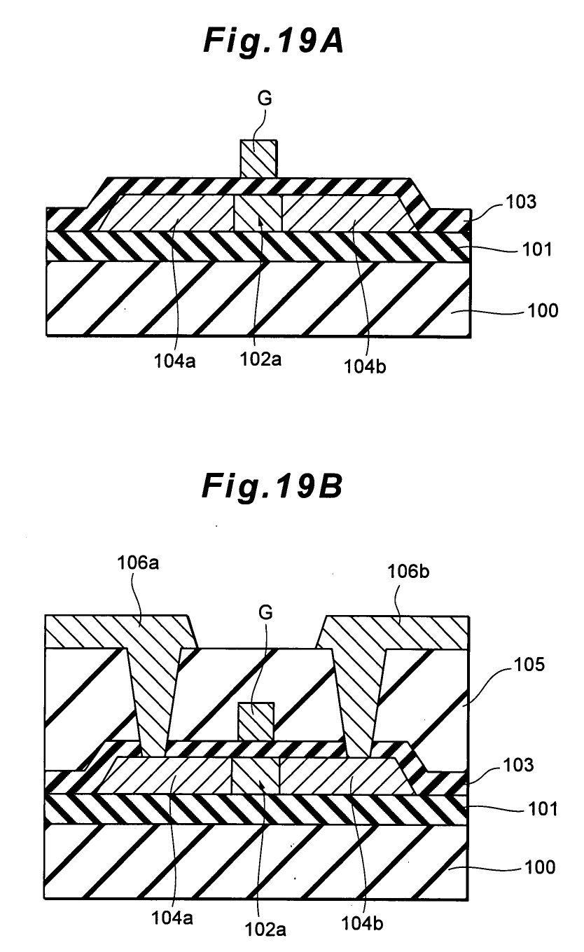

The method for fabricating a semiconductor device of the present invention is described below by way of example of a TFT (thin film transistor) fabricating process with reference to FIGS. 17 through 19. FIG. 17 is a cross section view showing the process for fabricating the semiconductor device in fabricating method 1 (FIG. 19 is similar).

A glass substrate (substrate, silica substrate, transparent substrate, insulating substrate) 100 is first prepared as shown in FIG. 17A. A glass substrate is used for liquid crystal display devices and the like, and a large surface area substrate may be used depending on the device. The shape of the glass substrate may be, for example, an approximate rectangle. A silicon oxide film is formed on the substrate 100 as an undercoat protective film (undercoat oxide film, undercoat insulating film) 101. The silicon oxide film is formed using, for example, plasma CVD (chemical vapor deposition) with TEOS (tetra ethyl ortho silicate) and oxygen gas as the source materials.

Then, for example, an amorphous silicon film 102 is formed over the undercoat protective film 101 as a semiconductor film. The silicon film 102 may be formed, for example, by a CVD method using SiH₄ (monosilane) gas.

Next, a photoresist film (hereinafter referred to simply as resist film) which is not shown in the figure is formed on the silicon film 102, and detached resist film (mask film, resist mask) remains when the resist film is exposed to light and developed (photolithography). Then, the silicon film 102, which is masked by the resist film, is etched to form a semiconductor element region (detached region). The resist film is then removed. The process of photolithography, etching, and resist film removal is referred to as patterning below.

Then, the silicon film 102 is subjected to a hydrogen flame process to recrystallize the silicon, as shown in FIG. 17B. That is, a substrate 100 is loaded on the stage 51 (refer to FIG. 1), and thermal processing is performed by scanning the top of the substrate 100 (silicon film 102) with the gas burner 22 to recrystallize the silicon film 102. In this case, the silicon film 102 is converted to a polycrystal silicon 102a, and a silicon oxide film 102b is formed on the surface of the polycrystal silicon 102a by the scanning of the hydrogen flame (FIG. 17C).

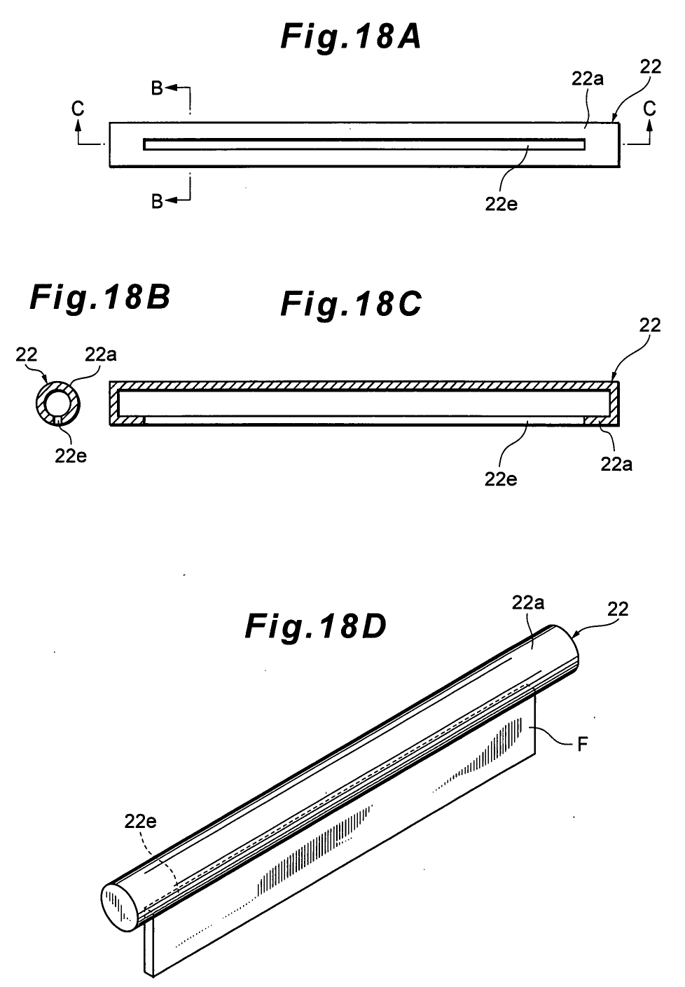

The structure of the gas burner 22 is described below. FIG. 18 shows a bottom view, cross section view, and another cross section view of the gas burner structure. Cross section views B and C respectively correspond to the B-B cross section and C-C cross section of the bottom view A. D is a perspective view.

As shown in FIG. 18, the guide tube 22a which conducts the hydrogen and oxygen gas mixture is provided with an approximately linear orifice (slit) 22e, and a line of flame F emerges from the orifice 22e. In the gas burner, the flame emerges directly from the guide tube 22a since the shield 22b (refer to FIG. 4) is not used.

According to the configuration of the gas burner 22, therefore, a line of flame F can be emitted, and uniformity of the flame temperature improved compared to when spot flames are emitted a plurality of orifices 22e, as shown in FIG. 16B. Thus, thermal processing uniformity is improved, and film irregularity is reduced. Furthermore, there is improved uniformity of the recrystallized silicon film thickness as well as the thickness of the silicon oxide film formed on the surface thereof as shown in FIG. 14 and FIG. 15. Crystallization rate dispersion is also reduced in the silicon film.

The crystallization rate can also be improved (for example, a crystallization rate of 90% or higher) if the process is performed with a reduced gap (30 mm or less) and relatively slow scanning speed (40 mm/s) (refer to sample E in FIG. 15).

Then, the silicon oxide film 102b is removed, and a silicon oxide film is formed as a gate insulating film 103 by, for example, thermal oxidation or CVD, as shown in FIG. 19A. Thermal oxidation may also be accomplished by the hydrogen flame process. Moreover, the silicon oxide film 102b may remain and used as, or part of, the gate insulating film.

A metal material such as aluminum (Al) or the like is then formed as a conductive film on the gate insulating film 103 by, for example, a spattering method. Next, the conductive film is patterned to a desired shape, and a gate electrode (gate electrode lead) G is formed. Rather than Al, a high melting point metal such as Ta (tantalum) may also be used as the conductive film. A conductive film may also be formed by sol-gel and MOD (metal-organic decomposition). That is, a conductive film may also be formed by applying and baking a metal compound solution. In this case, the solution may be applied to the gate electrode pattern via droplet discharge, and baked. The patterning step may be omitted in this instance.

Then, with the gate electrode G as a mask, and ionic impurities are injected into the polycrystal silicon film 102a (doped) to form source and drain regions 104a and 104b. Either of the regions 104a and 104b may be the source region and the other the drain region. Moreover, PH₃ (phosphine), for example, may be injected when the ionic impurities form an n-type semiconductor film, and B₂H₆ (diborane), for example, may be injected when the ionic impurity forms a p-type semiconductor film. Thereafter, thermal processing is performed to activate the ionic impurities.

An interlayer insulating film 105 is then formed on the gate electrode G, as shown in FIG. 19B. The interlayer insulating film 105 may be formed by plasma CVD using TEOS and oxygen gas as source materials. The interlayer insulating film 105 may also be formed by applying an insulating liquid material such as liquid polysilazane, and performing a thermal process (baking). When liquid polysilazane is used, a silicon oxide film is formed by baking. Liquid polysilazane is a liquid consisting of silazane dissolved in an organic solvent (for example, liquid xylene).

Next, contact holes are formed on the source and drain regions 104a and 104b by patterning the interlayer insulating film 105.

Thereafter, for example, an ITO (indium-tin oxide) film is formed as a conductive film 106 by a spattering method on the interlayer insulating film 105 which incorporates the internal contact holes. Rather than ITO, a metal material such as, for example, Al, Mo (molybdenum), Cu (copper) or the like may be used as the conductive film 106. The conductive film 106 may also be formed by sol-gel and MOD methods.

Then, the conductive film 106 is patterned in a desired shape, and source and drain electrodes (source and drain extractor electrodes, extractor leads) 106a and 106b are formed. Either of the electrodes 106a and 106b may be the source electrode and the other the drain electrode.

The TFT is completed in this step. The TFT may be used as a liquid crystal display device, drive element for pixel electrodes in electrophoresis device and organic EL devices, and logic circuit circumscribing the pixel region margin the TFT may also be used as an element configuring a memory, and logic circuit for driving a memory.

Although the hydrogen flame process is performed after patterning the silicon film 102 in the present fabricating method, the polycrystal silicon film 102a may also be patterned after being subjected to the hydrogen flame process.

Film irregularities caused by non-uniform flame temperature (substrate temperature) can be reduced and processed film characteristics can be improved since the flame in the hydrogen flame process is linear in the above fabricating method.

Fabricating Method 2

Although a linear flame is used in fabricating method 1, the hydrogen flame process may also be performed by adjusting a plurality of spot flames so as to have the ends of adjacent flames overlap.

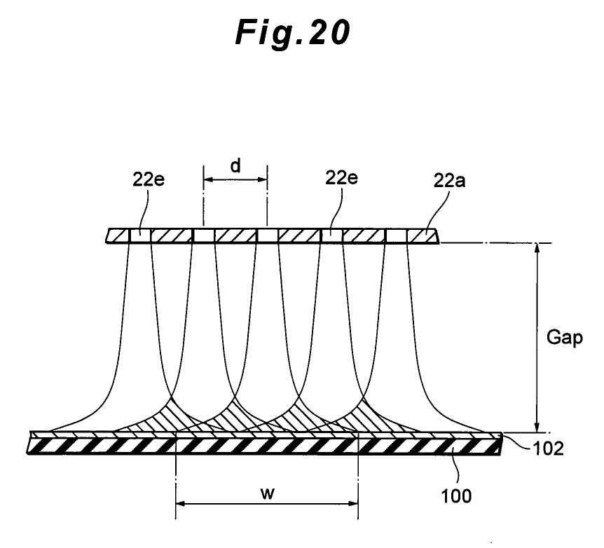

In this case, the hydrogen flame process is performed using a plurality of spot flames, as shown in FIG. 16B. Accordingly, (1) the spacing d of the orifices 22e, or (2) the distance (gap) between the substrate 100 and the gas burner 22 (orifices 22e) is adjusted so as have the individual spot flame overlap with the adjacent spot flame, as shown in FIG. 20. FIG. 20 shows the overlapping spot flames of the gas burner.

As shown in the figure, the uniformity of the flame temperature is improved by the flame overlaps (shaded areas in the figure) between the orifices 22e. In the figure, w refers to flame width. This w increases as the gap decreases.

For example, the flame overlap area can be adjusted by setting the spacing d so as to have the spot flames overlap, then finely adjusting the gap to the degree of 0 to 10 cm for each process. Thus, the uniformity of the thermal process is improved and film irregularity is reduced by adjusting the adjacent flames so as to overlap on the glass substrate (silicon film 102) 100, as was described in detail in fabricating method 1. Furthermore, there is improved uniformity of post recrystallization silicon film thickness as well as the thickness of the silicon oxide film formed on the surface thereof. Crystallization rate dispersion is also reduced in the silicon film. The crystallization rate can also be improved (for example, a crystallization rate of 90% or higher) if the process is performed with a reduced gap (30 mm or less) and relatively slow scanning speed (40 mm/s) (refer to sample E in FIG. 15).

Forming a plurality of approximately circular orifices also makes processing of the guide tube simple compared to forming a slit. The guide tube may be lengthened and the number of orifices easily increased for use in conjunction with a large surface area substrate.

Steps in the present fabricating method other than the step in which the silicon film 102 is subjected to the hydrogen flame process using the gas burner are identical to those of fabricating method 1 and, therefore, detailed description of these steps is omitted. The flame overlap may also be adjusted by the gas flow (gas pressure).

Fabricating Method 3

Although an approximately linear orifice is provided on the guide tube 22a in fabricating method 1, an approximately linear orifice may be provided on the shield 22b that circumscribes the guide tube 22a so as to adjust a line of flame to be emitted from the orifice, as described with reference to FIG. 5. That is, a nozzle having an approximately linear orifice may be disposed below the plurality of flames, with a plurality of flames emerging through the orifice. A line of flame may also be formed in this way.

In this instance, adjacent flames can be overlapped by adjusting the distance d of the orifices 22e and the distance between the orifice of the shield 22b and the orifices 22e, as described in fabricating method 2. Thus, the characteristics of the processed film can be improved as was described in detail in fabricating method 1. Furthermore, the effect of the simplicity of the guide tube processing described in fabricating method 2 is also obtained.

Steps in the present fabricating method other than the step in which the silicon film 102 is subjected to the hydrogen flame process using the gas burner are identical to those of fabricating method 1 and, therefore, detailed description of these steps is omitted.

Fabricating Method 4

Uniformity may also be achieved by a process in which a first scan by a plurality of flames is followed by a second scan which is shifted by ½ the distance between spots.

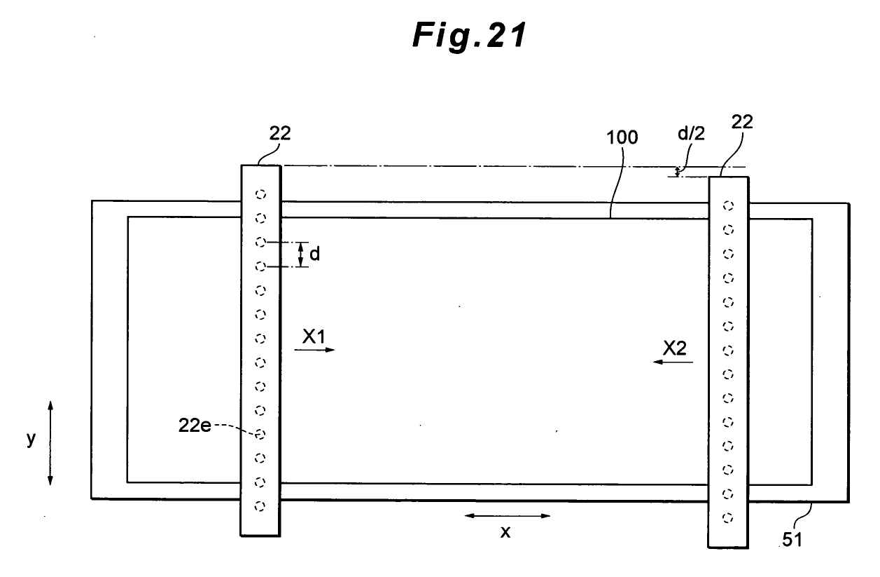

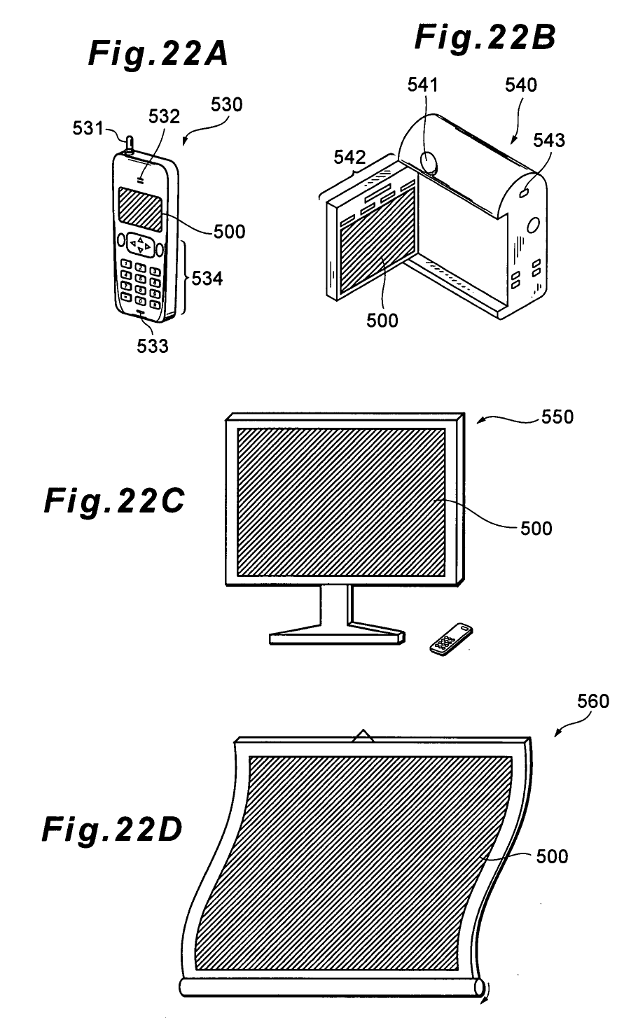

FIG. 21 is a top view showing the hydrogen flame scanning method in the present fabricating method. In this case, the hydrogen flame process is performed using a plurality of spot flames, as shown in FIG. 16B. As shown in FIG. 21, the gas burner 22 performs a first scan in the x1 direction from a first end to a second end of the substrate 100 in the x direction; then while at the second end in the x direction, the gas burner 22 is disposed at a position shifted one half the spacing d (d/2) in the y direction and subsequently the burner 22 performs a second scan from the second end to the first end (x2 direction). The first and second scans may also be accomplished by moving the substrate (stage 51) 100, and by moving the burner 22. The semiconductor fabricating apparatus used in the present fabricating method is configured so that the substrate 100 or the burner 22 is movable in the x and y directions.

In the present fabricating method, therefore, the unevenness in the process caused by the flame temperature differential induced by scanning directly below the gas outlets 22e: can be corrected in the second scan of the region scanned in the first scan by scanning between the gas outlets 22e where there is a relative reduction in flame temperature compared to simply scanning directly below the gas outlets 22e. Specifically, inadequate recrystallization occurring in the first scan is compensated by the second scan.

Steps in the present fabricating method other than the step in which the silicon film 102 is subjected to the hydrogen flame process using the gas burner are identical to those of fabricating method 1 and, therefore, detailed description of these steps is omitted.

Although two scans are performed in the present fabricating method, the first and second scans may be performed as a set, and a plurality of scans may also be performed. The direction of the second scan may also be set in the same x1 direction as the first scan. Furthermore, the destination of the first scan may be set as the starting point of the second scan to increase the processing speed. A plurality of scans may also be performed in the hydrogen flame processes of fabricating methods 1 through 3.

The thermal load on the substrate is reduced and thermal processing of large surface area substrate is possible using fabricating methods 1 through 4, as has been described in detail above. The uniformity of the thermal processing temperature is improved as are the characteristics of the fabricated semiconductor device.

Although an example of a thermal process (hydrogen flame process) performed when recrystallizing a silicon film 102 is described in fabricating methods 1 through 4 above, the present invention is not limited to this process and is widely applicable to various thermal processes.

For example, hydrogen flame processing may also be performed in the thermal process to thermally oxidize and activate ionic impurities when forming the gate insulating film, or the thermal process to bake the interlayer insulating film (polysilazane), and the sol-gel or MOD methods as described in fabricating method 1.

Process unevenness of the processed film can be reduced and film characteristics improved by applying this process to the fabricating methods above or to the gas burner (semiconductor fabricating apparatus).

The present invention is not limited to the examples described above inasmuch as the applications and examples described in the embodiments of the present invention may be suitably combined, modified, or improved as necessary.

Description of Electro-optic Device and Electronic Device

An electro-optic device (electronic device) using the semiconductor device (for example, TFT) formed by the methods in the above embodiment are described below.

The previously mentioned semiconductor device (TFT, for example) may be used as a drive element of an electro-optic device (display device). FIG. 22 shows an example of electronic devices using an electro-optic device. FIG. 22A shows an example of an application to a portable telephone, and FIG. 22B shows an example of an application to a video camera. FIG. 22C shows an example of an application to a television (TV), and FIG. 22D shows an example of an application to a roll-up type television.

As shown in FIG. 22A, a portable telephone 530 is provided with an antenna 531, audio output unit 532, audio input-unit 533, operation unit 534, and electro-optic device (display) 500. A semiconductor device formed by the present invention may be used (incorporated) as the electro-optic device.

As shown in FIG. 22B, a video camera 540 is provided with a video receiver 541, operation unit 542, audio input unit 543, and electro-optic device (display) 500. A semiconductor device formed by the present invention may be used (incorporated) as the electro-optic device.

As shown in FIG. 22C, a television 550 is provided with an electro-optic device (display) 500. A semiconductor device formed by the present invention may be used (incorporated) as the electro-optic device. The semiconductor device formed by the present invention can be used (incorporated) in a monitor device (electro-optic device) used a personal computer or the like.

As shown in FIG. 22D, a roll-up type television 560 is provided with an electro-optic device (display) 500. A semiconductor device formed by the present invention may be used (incorporated) as the electro-optic device.

The electronic devices having an electro-optic device additionally include large screen, personal computers, portable information devices (so-called PDA, electronic notebook) and the like, facsimile machines with display function, digital camera viewfinders, portable televisions, electrically lighted bulletin boards, advertising displays and the like.

What is claimed is:

1. A method for fabricating a semiconductor device comprising:
a step of forming a first film on a substrate; and
a step of performing a thermal process by scanning the first film with a flame of a gas burner using a hydrogen and oxygen gas mixture as a fuel,
wherein the flame of the gas burner is approximately linear.

2. A method for fabricating a semiconductor device comprising:
a step of forming a first film on a substrate;
a step of performing a thermal process by scanning the first film with a flame of a gas burner using a hydrogen and oxygen gas mixture as a fuel,
wherein the flame of the gas burner is a plurality of flames arrayed in an approximately linear fashion, and adjacent flames overlap on the substrate.

3. The method for fabricating a semiconductor device according to claim 2, wherein the overlap of the flames is adjusted by changing the distance between the gas burner and the substrate.

4. A method for fabricating a semiconductor device comprising:
a step of forming a first film on a substrate; and
a step of performing a thermal process by scanning the first film with a plurality of flames arrayed in an approximately linear fashion at fixed spacing using a hydrogen and oxygen gas mixture as a fuel,
wherein the step of performing a thermal process comprises
a first step of scanning the plurality of flames in a first direction; and
a second step of scanning in the first direction after moving the plurality of flames a distance ½ the fixed spacing distance in a second direction which is perpendicular to the first direction.

5. The method for fabricating a semiconductor device according to claim 4, wherein the first step is a step of scanning the plurality of flames from the side of a first end of the substrate; and
the second step is a step of scanning the plurality of flames from a second end on the side opposite the first end of the substrate.

6. The method for fabricating a semiconductor device according to claim 1, wherein the first film is a semiconductor film, and the semiconductor film is subjected to recrystallization by the thermal process.

7. A method for fabricating an electronic device which has the method for fabricating a semiconductor device according to claim 1.

8. A semiconductor fabricating apparatus comprising:
a gas supplying unit for supplying a hydrogen and oxygen gas mixture;
a gas burner for combusting the hydrogen and oxygen gas mixture to form a flame; and
a moving unit that relatively moves a substrate in a direction perpendicular to the flame of the gas burner,
wherein the gas burner conducts the hydrogen and oxygen gas mixture and emits the flame from an approximately linear orifice.

9. A semiconductor fabricating apparatus comprising;
a gas supplying unit for supplying a hydrogen and oxygen gas mixture;
a gas burner for combusting the hydrogen and oxygen gas mixture to form a flame; and
a moving unit that relatively moves a substrate in a direction perpendicular to the flame of the gas burner,
wherein the gas burner conducts the hydrogen and oxygen gas mixture, and emits the plurality of flames from a plurality of orifices formed in an approximately linear fashion at uniform pitch.

10. The semiconductor fabricating apparatus according to claim 9 further comprising a nozzle having an approximately linear orifice disposed below the plurality of flames, wherein the plurality of flames are emitted through the orifice.

11. The semiconductor fabricating apparatus according to claim 9, wherein the moving unit controls movement in a first direction and a second direction which is perpendicular to the first direction.
